(19) United States
(12) Patent Application Publication
(10) Pub. No.: US 2026/0079210 A1
(43) Pub. Date: Mar. 19, 2026

(54) BATTERY ENERGY ESTIMATION SYSTEM AND METHOD FOR BATTERIES

(71) Applicant: Vertiv Corporation, Westerville, OH (US)

(72) Inventors: Prashant Prakash Hirave, Kolhapur (IN); Sameer Upasani, Wadgaonsheri (IN); Avinash Adinath Patil, Dist. Kolhapur (IN); Pranav Aloni, Nagpur (IN)

(21) Appl. No.: 19/332,462

(22) Filed: Sep. 18, 2025

(30) Foreign Application Priority Data
Sep. 18, 2024 (IN) 202421070684

(51) Int. Cl. G01R 31/367; G01R 31/371; G01R 31/3835; H01M 10/42

(52) U.S. Cl. CPC G01R 31/367; G01R 31/371; G01R 31/3835; H01M 10/4285

(57) ABSTRACT

The present invention provides a system for energy estimation in batteries, comprising a battery set-up module configured to define a configuration of one or more batteries. The system has a state-of-charge (SOC) estimation module that comprises a calculation module configured to obtain battery specifications and compute system parameters, a graph plotting module configured to generate voltage-energy graph at pre-defined load conditions, and an estimation module configured to determine SOC and runtime values based on discharge voltage and voltage-energy graphs. It also has an analysis module configured to uninterruptedly monitor and analyze battery voltage, SOC, and runtime, a notification module configured to initiate warnings when the monitored voltage SOC and runtime approach predetermined thresholds, and a shut-down module to enable a safe shutdown and backup operation.

### CROSS-REFERENCE TO RELATED APPLICATIONS

The present application claims the benefit of India Provisional Patent Application Number 202421070684 filed Sep. 18, 2024, which is incorporated herein by reference in its entirety.

### TECHNICAL FIELD

The present invention relates to the field of battery management systems and, more particularly, to systems and methods for estimating remaining energy and runtime in batteries using voltage-energy characteristics.

### BACKGROUND OF THE INVENTION

The widespread use of lithium-ion batteries in electronics, EVs, and renewable systems demands accurate state of charge (SoC) and runtime estimation, yet current methods like Coulomb counting, voltage-based estimation, and Kalman filtering face challenges such as cumulative errors, sensitivity to conditions, and high computational demands. These limitations hinder performance, leading to power failures and inefficient use. Therefore, there is a critical need for a more robust system and method that overcomes these drawbacks to improve accuracy, reliability, and efficiency in lithium-ion battery management.

### SUMMARY OF THE INVENTION

This summary is provided to introduce aspects related to a system and method for energy estimation in batteries. This enables to analyze and predetermine the thresholds for a battery runtime and protect it from further damage.

According to an embodiment of the present invention, a system for energy estimation in batteries is provided. The system comprises a battery set-up module configured to define a configuration of one or more batteries. It further includes a state-of-charge (SOC) estimation module comprising a calculation module configured to obtain battery specifications and compute system parameters, a graph plotting module configured to generate voltage-energy graph at pre-defined load conditions, and an estimation module configured to determine SOC and runtime values based on discharge voltage and voltage-energy graphs. The system also includes an analysis module configured to uninterruptedly monitor and analyze battery voltage, SOC, and runtime, a notification module configured to initiate warnings when the monitored voltage SOC and runtime approach predetermined thresholds, and a shut-down module to enable safe shutdown and backup operations.

In an embodiment, the battery set-up module configures the batteries in at least one of series, parallel, modular, or hybrid arrangements.

In an embodiment, the calculation module computes at least one of instantaneous efficiency, peak power capability, temperature-adjusted capacity, and maximum allowable backup time.

In an embodiment, the estimation module determines deliverable energy based on present energy, load derating factors, and temperature derating factors.

In an embodiment, the analysis module continuously evaluates one or more of SOC percentage, runtime remaining, terminal voltage, and internal resistance.

In an embodiment, the notification module initiates controlled backup or shutdown operations when SOC falls below a threshold value using the shutdown module.

In a further embodiment, the notification module transmits alerts via at least one of a visual indicator, audible indicator, or network communication protocol.

In a further embodiment, the SOC estimation module is implemented at least partially in firmware, software, or a combination thereof stored in a non-transitory memory and executed by a processor.

In a further embodiment, the system is integrated into an uninterruptible power supply (UPS).

In an embodiment, the UPS comprises a drop-in replacement lithium battery module for an existing valve-regulated lead-acid (VRLA) system.

According to another embodiment, a method for energy estimation in batteries comprises obtaining battery specifications including at least one of capacity, voltage, and energy density. The method incorporates calculating system parameters including at least one of instantaneous efficiency, maximum allowable backup time, and maximum allowable load, plotting voltage-energy graphs at predefined load conditions, estimating state-of-charge (SOC) and runtime based on end-of-discharge voltage and the voltage-energy graphs, monitoring voltage, SOC, and runtime values for the battery, generating notifications when the voltage, SOC, or runtime approach predetermined thresholds, and shutting down or initiating backup operations in case of a warning.

In an embodiment, monitoring comprises real-time measurement of instantaneous power delivered to or from the battery.

In an embodiment, the method further comprising transmitting end-of-discharge warnings or low-voltage warnings to a user interface or remote monitoring system.

In an embodiment, the method further comprising initiating safe shutdown of a connected load when SOC percentage is below a threshold.

In an embodiment, the method further comprising adapting the method to operate in at least one of a single-phase UPS, a modular UPS, or a hybrid UPS.

According to another embodiment, it includes a non-transitory computer-readable medium storing instructions that, when executed by a processor, cause a system to perform the method.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying figures of the drawing, which are included to provide a further understanding of general aspects of the system/method, are incorporated in and constitute a part of this specification. These illustrative aspects of the system/method, and together with the detailed description, explain the principles of the system. No attempt is made to show structural details in more detail than is necessary for a fundamental understanding of the system and various ways in which it is practiced. The following figures of the drawing include:

FIG. 1 illustrates a block diagram for a system for battery energy estimation in lithium batteries;

FIG. 2 illustrates the working of the battery energy estimation model;

FIG. 3 illustrates a flowchart exemplifying the method for battery energy estimation in lithium batteries; and

FIGS. 4A and 4B depict Voltage-Energy graphs.

In the appended figures, similar components and/or features may have the same numerical reference label. Further, various components of the same type may be distinguished by following the reference label with a letter. If only the first numerical reference label is used in the specification, the description is applicable to any one of the similar components and/or features having the same first numerical reference label irrespective of the suffix.

### DETAILED DESCRIPTION OF THE INVENTION

Illustrative embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

In present times, lithium-ion battery technology has emerged as the cornerstone of modern energy storage, powering applications ranging from uninterruptible power supplies (UPS) and data center backup to electric vehicles, renewable energy systems, and consumer electronics. Their widespread adoption is driven by advantages such as high energy density, longer cycle life, compact form factor, and faster charge-discharge rates when compared to traditional valve-regulated lead-acid (VRLA) batteries or system. Despite these benefits, accurate estimation of critical parameters such as state-of-charge (SOC), remaining energy, and runtime continues to be a challenge, primarily because lithium batteries exhibit nonlinear voltage profiles, strong dependence on load conditions, and sensitivity to temperature variations. Existing methods like Coulomb counting, voltage-based estimation, and Kalman filtering have been deployed, but each suffers from inherent limitations including drift errors, inaccurate transient responses, or computational complexity. As global reliance on resilient and predictable backup power grows, particularly in mission-critical sectors such as cloud infrastructure, telecommunications, and industrial automation, the need for improved energy estimation systems that can deliver accuracy, adaptability, and seamless integration with UPS systems has become more pronounced than ever.

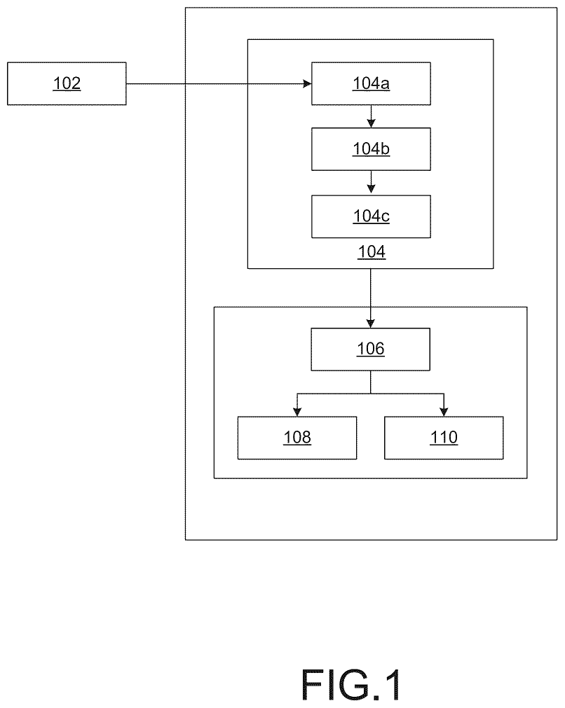

To overcome the aforementioned drawbacks, the present disclosure envisages a battery energy estimation system and method which will be described with reference to FIGS. 1 to 4B.

FIG. 1 illustrates a block diagram for a system for battery energy estimation in lithium batteries in accordance with one embodiment of the present disclosure. The system 100 comprises a battery set-up module 102, a SOC estimation module 104, an analysis module 106, notification module 108, and shut-down module 110. The SOC estimation module also comprises a calculation module 104a, a graph plotting module 104b, and an estimation module 104c.

The battery set-up module 102 can be configured to conduct battery configuration as per the system requirements. The various battery configurations can include series configuration, parallel configuration, series-parallel configuration, grid configuration, modular configuration, cascade configuration, hybrid configuration, and stack configuration. The SOC estimation module 104 can be configured to comprise the calculation module 104a, graph plotting module 104b, and estimation module 104c. The SOC estimation module 104 is implemented at least partially in firmware, software, or a combination thereof stored in a non-transitory memory and executed by a processor. The calculation module 104a can be configured to obtain battery characteristics including maximum battery capacity, voltage, energy density, charge and discharge rates, cycle life, self-discharge rate, internal resistance, temperature range, chemistry, form factor, and size, and calculate system parameters including instantaneous efficiency, peak power capability, temperature-adjusted capacity, maximum allowable backup time, and maximum allowable load. The graph plotting module 104b can be configured to plot voltage energy graphs at pre-defined load conditions. The estimation module 104c can be configured to estimate the state of charge and remaining runtime for the battery based on the end-of-discharge voltage and the voltage energy graphs plotted by the graph plotting module 104b. The analysis module 106 can be configured to continuously monitor and analyze the battery voltage, SOC percentage, and runtime. The notification module 108 can be configured to initiate warnings when battery voltage approaches the end-of-discharge (EOD) voltage value and when SOC percentage and runtime fall below pre-defined thresholds to enable safe shutdown and backup operations using the shut-down module 110.

The battery set-up module 102 defines the arrangement of one or more lithium batteries in series, parallel, series-parallel, modular, hybrid, or cascade configurations. It accepts specifications such as capacity, nominal voltage, cycle life, and internal resistance, and prepares these values for downstream computation.

The SOC estimation module 104 comprises three sub-components: a calculation module 104a, a graph plotting module 104b, and an estimation module 104c. The calculation module 104a computes system parameters including instantaneous efficiency, maximum allowable backup time, and load tolerance. The graph plotting module 104b generates voltage-energy graphs at multiple load conditions. The estimation module 104c derives SOC and runtime values using end-of-discharge voltage points mapped to the plotted curves.

The estimation module 104c comprises a battery energy estimation model module that incorporates empirical discharge data collected under various load conditions. In one embodiment, the model comprises a plurality of load tables, that is, at least, eleven load tables, each containing a plurality of discrete energy points, preferably, thirty-two discrete energy points. The module further calculates deliverable energy by factoring present energy values, load derating, and temperature derating effects.

The analysis module 106 continuously monitors SOC, runtime, terminal voltage, and instantaneous power. It ensures that the estimated parameters are updated in real-time and compared against system thresholds.

The notification module 108 generates alerts and warnings when monitored parameters approach defined thresholds. The notifications may include end-of-discharge warnings and low-voltage warnings, and may be communicated via visual displays, audible indicators, or network communication protocols to a user interface or a remote monitoring system. In certain embodiments, the notification module 108 transmits a notification to the shut-down module 110 that initiates controlled shutdown procedures to ensure safe system operation. The UPS may also comprise a drop-in replacement lithium battery module for an existing valve-regulated lead-acid (VRLA) system.

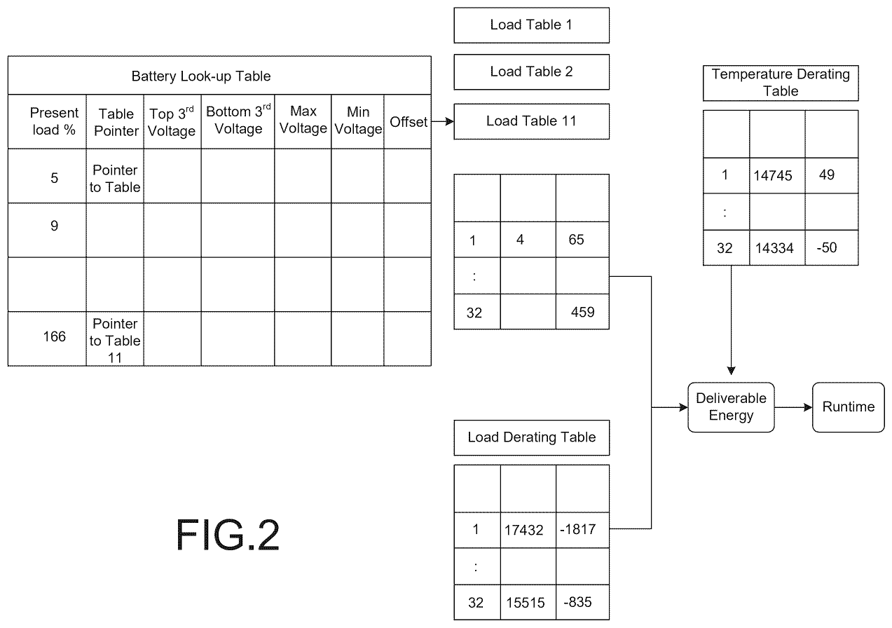

FIG. 2 illustrates a schematic representation of the battery energy estimation model. The model includes a look-up table of discharge data, captured across different load conditions such as 3 kW, 5 kW, and 10 kW. Each load table comprises multiple discrete energy points. The model interpolates between the data points to estimate SOC with greater precision than conventional approaches.

The model further computes deliverable energy by combining present energy values with derating factors. Load derating accounts for efficiency variations under different current draws, while temperature derating reflects capacity shifts due to environmental conditions. By combining these variables, the model produces more accurate SOC and runtime values than traditional Coulomb counting or voltage-only methods.

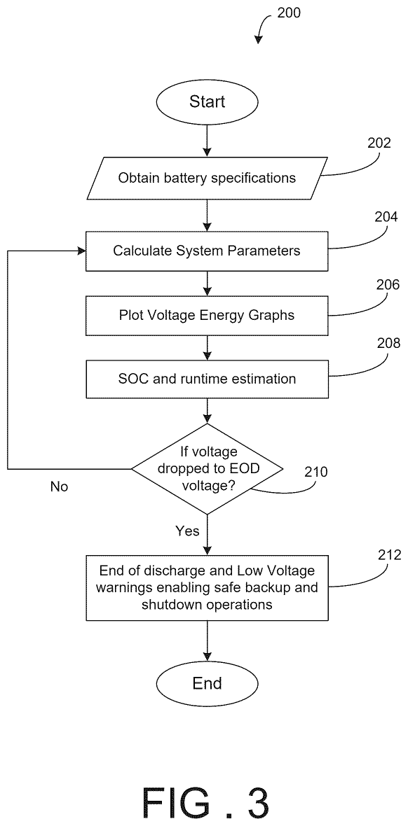

FIG. 3 presents a flowchart of a method 200 for battery energy estimation. At step 202, battery specifications are obtained, including rated capacity, voltage, energy density, and expected cycle life. At step 204, system parameters are calculated, including instantaneous efficiency and maximum allowable backup time. At step 206, voltage-energy graphs are plotted for one or more predefined load conditions.

At step 208, SOC and runtime are estimated by correlating end-of-discharge voltage values with the voltage-energy graphs generated in step 206. At step 210, the system continuously monitors the SOC, runtime, and voltage. At step 212, notifications are generated when monitored values approach or fall below predefined thresholds. In some embodiments, the method further includes automatically initiating safe shutdown of a connected load upon receiving an end-of-discharge signal.

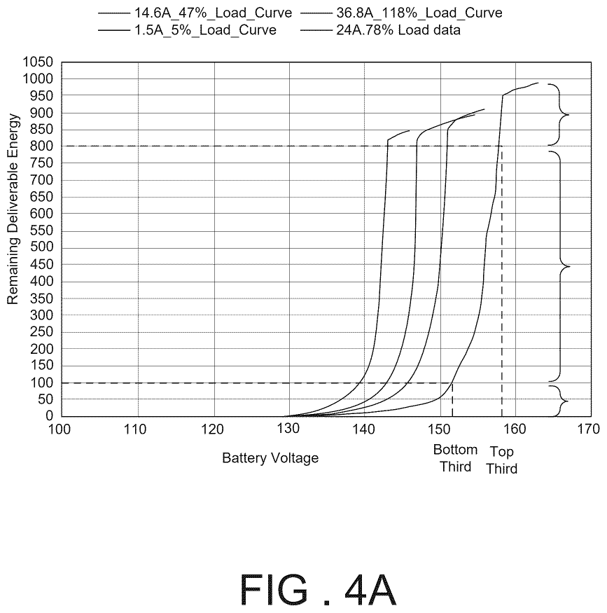

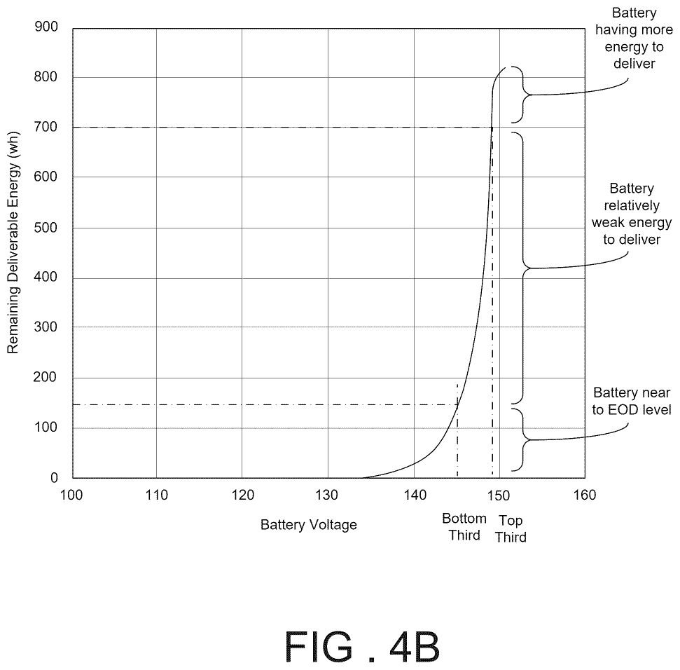

FIG. 4A and FIG. 4B illustrate representative voltage-energy graphs for lithium batteries under varying load conditions. The x-axis corresponds to the energy or SOC percentage, while the y-axis corresponds to the battery voltage.

The curves demonstrate that voltage response varies depending on the applied load. At higher loads, the voltage declines more rapidly compared to lower loads. The figures further identify reference thresholds such as a top-third voltage boundary and a bottom-third voltage boundary. These thresholds are employed by the system to refine SOC estimations and trigger warnings when the battery approaches end-of-discharge.

By storing these curves in the battery energy estimation model as discrete energy points, the system can dynamically estimate SOC and runtime with improved accuracy across a wide range of operating conditions.

The present disclosure described herein above has several technical advantages including, but not limited to a system and a method for battery energy estimation in lithium batteries, that prolongs battery life with enhanced and effective battery management and operation. It enhances the system reliability with improved battery and device performance. It avoids catastrophic incidents like thermal runaway, electrolyte leakage, overheating, gas emission, and explosion risk. Further, this prevents loss of work and time through safe backup and shutdown operations in various electronic systems. The present invention also enables prompt end-of-charge and voltage fluctuations notifications to the users. It facilitates higher accuracy compared to existing systems in state-of-charge (SOC) and runtime estimations for lithium batteries. The same allows rapid time to market with seamless adaptability and integration into existing devices and systems, requiring no additional hardware. It also protects system components during stress-inducing events such as system crashes, power failures, and voltage fluctuations. The system also facilitates cost savings by preventing damage to electronic devices and components caused by abrupt or unsafe battery management operations. It also provides advanced battery management technology that exceeds current standards, and offers flexibility and scalability, enabling effortless integration with diverse electronic devices and components. Further, it provides a robust battery system capable of sustaining and reliably delivering power during high-demand situations and peak loads.

The methods, systems, devices, graphs, and/or tables discussed herein are examples. Various embodiments may omit, substitute, or add various procedures or components as appropriate. For instance, in alternative embodiments, the methods may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples and do not limit the scope of the disclosure or claims. Additionally, the techniques discussed herein may provide differing results with different types of context awareness classifiers.

Unless defined otherwise, all technical and scientific terms used herein have the same meaning as commonly or conventionally understood. As used herein, the articles “a” and “an” refer to one or to more than one (i.e., to at least one) of the grammatical object of the article. By way of example, “an element” means one element or more than one element. “About” and/or “approximately” as used herein when referring to a measurable value such as an amount, a temporal duration, and the like, encompasses variations of +20% or +10%, +5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

As used herein, including in the claims, “and” as used in a list of items prefaced by “at least one of” or “one or more of” indicates that any combination of the listed items may be used. For example, a list of “at least one of A, B, and C” includes any of the combinations A or B or C or AB or AC or BC and/or ABC (i.e., A and B and C). Furthermore, to the extent more than one occurrence or use of the items A, B, or C is possible, multiple uses of A, B, and/or C may form part of the contemplated combinations. For example, a list of “at least one of A, B, and C”may also include AA, AAB, AAA, BB, etc.

While illustrative and presently preferred embodiments of the disclosed systems, methods, and/or machine-readable media have been described in detail herein, it is to be understood that the inventive concepts may be otherwise variously embodied and employed, and that the appended claims are intended to be construed to include such variations, except as limited by the prior art. While the principles of the disclosure have been described above in connection with specific apparatuses and methods, it is to be clearly understood that this description is made only by way of example and not as limitation on the scope of the disclosure.

### LIST OF REFERENCE NUMERALS

100—System
102—Battery Set-Up Module
104—SOC Estimation Module
104a—Calculation Module
104b—Graph Plotting Module
104c—Estimation Module
106—Analysis Module
108—Notification Module
110—Shut-down Module

What is claimed is:

1. A system for energy estimation in batteries, comprising:
a battery set-up module configured to define a configuration of one or more batteries;
a state-of-charge (SOC) estimation module comprising:
a calculation module configured to obtain battery specifications and compute system parameters;
a graph plotting module configured to generate voltage-energy graph at pre-defined load conditions;
an estimation module configured to determine SOC and runtime values based on discharge voltage and voltage-energy graphs;
an analysis module configured to uninterruptedly monitor and analyze battery voltage, SOC, and runtime;
a notification module configured to initiate warnings when the monitored voltage SOC and runtime approach predetermined thresholds, and
a shut-down module to enable a safe shutdown and backup operation.

2. The system of claim 1, wherein the battery set-up module configures the batteries in at least one of series, parallel, modular, or hybrid arrangements.

3. The system of claim 1, wherein the calculation module computes at least one of instantaneous efficiency, peak power capability, temperature-adjusted capacity, and maximum allowable backup time.

4. The system of claim 1, wherein the estimation module determines deliverable energy based on present energy, load derating factors, and temperature derating factors.

5. The system of claim 4, wherein the estimation module comprises a battery energy estimation model module comprising a plurality of load tables containing a plurality of discrete energy points.

6. The system of claim 5, wherein the battery energy estimation model module calculates deliverable energy by factoring present energy values, load derating, and temperature derating effects.

7. The system of claim 1, wherein the analysis module evaluates one or more of SOC percentage, runtime remaining, terminal voltage, and internal resistance.

8. The system of claim 1, wherein the notification module initiates controlled backup or shutdown operations when SOC falls below a threshold value using the shut-down module.

9. The system of claim 1, wherein the notification module transmits alerts via at least one of a visual indicator, audible indicator, or network communication protocol.

10. The system of claim 1, wherein the SOC estimation module is implemented at least partially in firmware, software, or a combination thereof stored in a non-transitory memory and executed by a processor.

11. The system of claim 1, wherein the system is integrated into an uninterruptible power supply (UPS).

12. The system of claim 11, wherein the UPS comprises a drop-in replacement lithium battery module for an existing valve-regulated lead-acid (VRLA) system.

13. A method for energy estimation in batteries, the method comprising:
obtaining battery specifications including at least one of capacity, voltage, and energy density;
calculating system parameters including at least one of instantaneous efficiency, maximum allowable backup time, and maximum allowable load;
plotting voltage-energy graphs at predefined load conditions;
estimating state-of-charge (SOC) and runtime based on end-of-discharge voltage and voltage-energy graphs;
monitoring voltage, SOC, and runtime values for the battery;
generating notifications when the voltage, SOC, or runtime approach predetermined thresholds; and
shutting down or initiating backup operations in case of a warning.

14. The method of claim 13, wherein monitoring comprises real-time measurement of instantaneous power delivered to or from the battery.

15. The method of claim 13, further comprising transmitting end-of-discharge warnings or low-voltage warnings to a user interface or remote monitoring system.

16. The method of claim 13, further comprising initiating safe shutdown of a connected load when SOC percentage is below a threshold.

17. The method of claim 13, further comprising adapting the method to operate in at least one of a single-phase UPS, a modular UPS, or a hybrid UPS.

18. A non-transitory computer-readable medium storing instructions that, when executed by a processor, cause a system to perform the method of claim 13.
